(19) United States
(12) Patent Application Publication
(10) Pub. No.: US 2004/0017303 A1
(43) Pub. Date: Jan. 29, 2004

(54) Counter arrangement with recover function

(75) Inventor: Myron Loewen, Chandler, AR (US)

Correspondence Address: PAUL N. KATZ, BAKER BOTTS L.L.P., ONE SHELL PLAZA, 901 LOUISIANA STREET, HOUSTON, TX, 77002-4995, US

(73) Assignee: Microchip Technology Incorporated

(21) Appl. No.: 09/853,260

(22) Filed: May 11, 2001

(51) Int. Cl. H03M 7/04

(52) U.S. Cl. 341/98

(57) ABSTRACT

A counter arrangement comprises a plurality of counter registers and at least the same number of checksum registers being controlled by control means. The counter control means change the content of only one of the counter registers for each change in the counting sequence and comprise means to update the checksum registers, whereby the content of each checksum registers is defined by an associated function which allows recovery of the content of each counter register and a function performed on the content of all checksum registers results in a constant value to validate the checksum.

### FIELD OF THE INVENTION

The present invention relates generally a counter arrangement, in particular a counter arrangement realized within a microcontroller or microprocessor or a stand-alone counter arrangement usable in many applications, such as digital odometer.

### BACKGROUND OF THE INVENTION

Counter arrangements, in particular counter arrangements with a recover function are well known in the art. For example, PCT/US97/02986 discloses an arrangement including a gray code counter. Additional memory is used to verify whether a write process has been successfully performed. Therefore, such an arrangement allows to control whether the content of a counter register is valid. However, such an arrangement allows only to identify whether a specific bit of a gray code counter has been written correctly or not. Usually a microprocessor or microcontroller writes to a memory cell, such as a byte or word, within a single cycle. In case of a voltage failure or other influences this write cycle could be corrupted and the whole content of this memory cell may be wrong. In an arrangement according to the prior art additional memory and resources are necessary to provide complete redundancy so that the content of a counter is recoverable at any circumstances.

### SUMMARY OF THE INVENTION

Therefore, the present application discloses exemplary embodiments which overcome the above mentioned problems as well as other shortcomings and deficiencies of existing technologies. General requirements for a counter arrangement according to the present application are that the size of a checksum register is equal or greater than the size of the counter registers and that the registers are updated sequentially one at a time. Thus, the present application provides the advantage of a minimal size for a checksum register and a minimal number of registers updated per increment or decrement. This also results in minimized hardware and software complexity.

In one exemplary embodiment according to the present application a counter arrangement comprises a plurality of counter registers and at least the same number of checksum registers being controlled by control means. The counter control means change the content of only one of the counter registers for each change in the counting sequence and comprise means to update the checksum registers, whereby the content of each checksum registers is defined by an associated function which allows recovery of the content of each counter register and a function performed on the content of all checksum registers results in a constant value.

In another exemplary embodiment the counter arrangement comprises a control unit, first, second, and third registers coupled with said control unit, fourth, fifth, and sixth registers coupled with said control unit, and first, second, and third functional units each having two inputs and an output. The inputs of the first functional unit are coupled with the first and second register, respectively and the output with the fourth register. The inputs of the second functional unit are coupled with the second and third register, respectively and the output with the fifth register. The inputs of the third functional unit are coupled with the first and third register, respectively and the output with the sixth register. The control unit performs a counter function on the first, second, and third registers such that the content of only one of the counter registers changes for each change in a counting sequence.

A method for operating a counter comprising a plurality of counter registers and at least the same number of checksum registers, comprises the steps of:

changing the value of only one of the counter registers with every change in a counting sequence;

calculating the value of the associated checksum registers as a function of the content of at least two counter registers such that a checksum calculated from all checksum registers results in a constant value.

### BRIEF DESCRIPTION OF THE DRAWINGS

A more complete understanding of the present disclosure and advantages thereof may be acquired by referring to the following description taken in conjunction with the accompanying drawings, in which like reference numbers indicate like features, and wherein:

FIG. 1 is a block diagram of a counter arrangement in accordance with one exemplary embodiment of the present application;

FIG. 2 is a block diagram of a counter arrangement in accordance with another exemplary embodiment of the present application;

FIG. 3 is flow chart showing the method in accordance one embodiment of the present application;

FIG. 4 is another flow chart showing the method in accordance with another embodiment of the present application.

FIG. 5 is a block diagram of an exemplary embodiment of a base-2ⁿ-gray code converter;

FIG. 6 is a block diagram of a base-2ⁿ-gray code counter;

FIG. 7 is a flow chart showing the conversion from a base-2ⁿ-gray code into a binary code; and

FIG. 8 is a flow chart showing the conversion from a binary code into a base-2ⁿ-gray code.

### DETAILED DESCRIPTION OF THE PREFERRED EMBODIMENTS

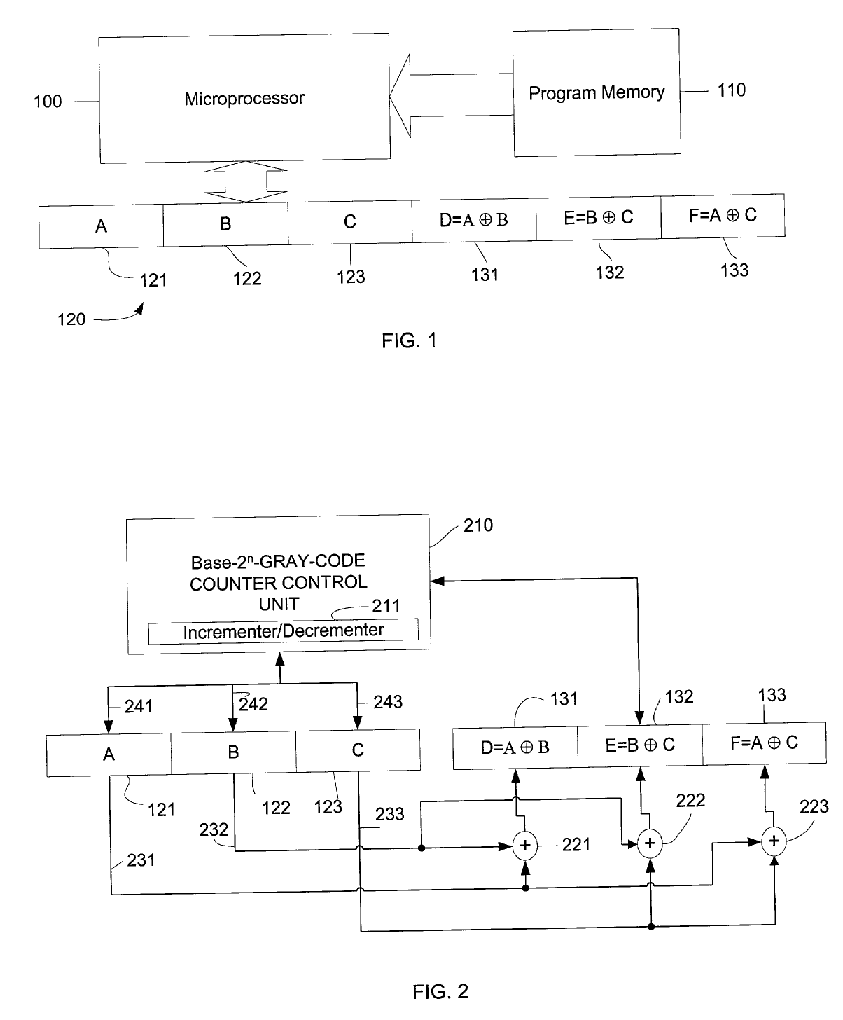

Turning to the drawings, exemplary embodiments of the present application will now be described. FIG. 1 depicts a typical arrangement of counter arrangement implemented within a microprocessor or microcontroller. A microprocessor 100 or any central processing unit of a microcontroller is coupled with a program memory 110. Furthermore a plurality of non-volatile memory cells 120 are connected to the microprocessor 100. The plurality of non-volatile memory cells 120 can be part of a data memory block (not shown) or be a single separate unit as shown. The non-volatile memory can be a Flash EPROM, EEPROM, or any other suitable memory. Non-volatile memory 120 in this exemplary embodiment is comprised of six memory cells 121, 122, 123, 131, 132, and 133. Each memory cell 121, 122, 123, 131, 132, and 133 has the same bit width, such as 2 bit, 4 bit, 8 bit, 16 bit, etc. depending on the structure of the non-volatile memory. The number of cells required is determined by the maximum number the counter should be able to count.

The arrangement as shown in FIG. 1 forms a counter which can recover from any type of interruption, such as brownouts, resets, electromagnetic influences, voltage influences, etc. at any point during updating. To this end, the counter proper consists of memory cells 121, 122, and 123. These memory cells form a gray code type counter with respect to the fact that only one of the three cells changes with any increment or decrement of the counter. In other words, no strict gray code has to be used unless each memory cell 121, 122, 123 consists of only a single bit. In a typical application memory cells 121, 122, 123, 131, 132, and 133 have a bit width of 8 or 16 bits. Thus, a maximum count number of 16777216 or about 2.8●10¹⁴, respectively is possible. A suitable gray code is a 2ⁿ-base-gray code. For example, if n=2, the sequence for three memory cells would be: 000, 001, 002, 003, 013, 012, 011, 010, 020, 021, . . . each of the three digit representing the content of one 2-bit memory cell. Other possible sequences are, for example, N-base-gray-codes using three-level logic, such as, −1, 0, +1, or gray codes that do not fill up the entire binary space, such as a base-9 counter in 2⁴ or 3³ sized elements.

Total recovery from any malfunctioning during writing of a counter register is possible through only three additional memory cells 131, 132, and 133. Memory cell 131 contains the Exclusive Ored content of memory cells 121 and 122; namely D=A⊕B. Memory cell 132 contains the Exclusive Ored content of memory cells 122 and 123; namely E=B⊕C and memory cell 133 contains the Exclusive Ored content of memory cells 121 and 123; namely F=A⊕C.

The principle behind this arrangement is that the additional memory cells 131, 132, 133 are used on one hand as a checksum and on the other hand as recovery means. Verifying the checksum is critical to determine whether the detected error occurred during the update of the counter or the checksum. To this end, an arithmetic or logical operation of the content of the counter registers 121, 122, 123 defines the content of the additional memory cells 131, 132, and 133. In the exemplary embodiment, a logical operation has been chosen. The EXCLUSIVE OR function shows the characteristic that if performed with the same operand, such as A⊕A, the result will be zero. Thus, the logical operation of

checksum=D⊕E⊕F=(A⊕B)⊕(B⊕C)⊕(A⊕C)

can be transferred into

checksum=(A⊕A)⊕(B⊕B)⊕(C⊕C)

which results in

checksum=(0)⊕(0)⊕(0)=0.

Furthermore, recovery is possible as each content of the counter memory cells 121, 122, and 123 can also be defined by one of the checksum memory cells in combination with the content of one of the other counter memory cells. For example, memory cell 121 can also be defined by

A=D⊕B=(A⊕B)⊕B=A⊕(0); or

A=F⊕C=(A⊕C)⊕C=A⊕(0);

Recovery for the other counter memory cells 122 and 123 is performed accordingly. Any other suitable arithmetic or logical operation can be used to generate the same result. For example, instead of an EXCLUSIVE OR function simple arithmetic functions + and − can be used. Registers (memory cells) D, E, and F would then be defined as D=A−B; E=B−C; and F=C−A. For calculating the checksum a simple addition function can be used.

checksum=D+E+F=(A−B)+(B−C)+(C−A)=A−A+B−B+C−C=0.

Recovery of the counter register content can be performed according to the used arithmetic function as described above. In this embodiment the checksum register can provide an additional bit to determine the sign of the content or modulus arithmetic can be used. As can be readily seen, other logical or arithmetic functions can be used to allow the function of checksum and recovery with only a minimum of additional memory cells/registers. The result of the checksum calculation has to be a constant independent of the content of the counter registers. Thus a division/multiplication function is also possible and the checksum would, for example, result in a ‘1’. In the following exemplary embodiments the EXCLUSIVE OR function is used as an exemplary logical/arithmetic function.

FIG. 2 depicts a second exemplary embodiment showing a stand alone counter arrangement. A counter control unit is coupled with memory cells 121, 122, 123 through lines 241, 242, and 243, respectively. Furthermore, a counter control unit 210 controls the content of counter memory cells 121, 122, and 123 and is coupled as well with memory cells 131, 132, 133. Counter control unit comprises an incrementer/decrementer unit 211 for incrementing/decrementing the content of the different counter registers 121, 122, and 123 through lines 241, 242, and 243, respectively. Memory cell 121 is coupled with the first inputs of EXCLUSIVE OR gates 221 and 223 via lines 231. Memory cell 122 is coupled with the second input of EXCLUSIVE OR gate 221 and the first input of EXCLUSIVE OR gate 222 via lines 232. Memory cell 123 is coupled with the second inputs of EXCLUSIVE OR gates 222 and 223 via lines 233. The output of EXCLUSIVE OR gate 221 is connected with memory cell 131, the output of EXCLUSIVE OR gate 222 with memory cell 132 and the output of EXCLUSIVE OR gate 223 with memory cell 223. Counter control unit 210 comprises an incrementer/decrementer 211 which can be selectively coupled with one of the memory cells 121, 122, or 123. To this end, the incrementer reads the content of the selected memory cell 121, 122, or 123, increments or decrements it and writes the new value back into the respective memory cell 121, 122, or 123. These memory cells 131, 132, and 133 form a checksum and through those memory cells in combination with memory cells 121, 122, and 123 a full recovery of the counter is possible as will be explained now in more detail.

The counter consisting of memory cells 121, 122, and 123, which in this example are assumed to have a bit width of 8 bits, is incremented as follows. For example, starting at a counter value of 0, memory cell 123 is incremented up to 255. With the next increment memory cell 122 is incremented by I and memory cell 123 and 121 remain unchanged. Thus, the next increments will again only affect memory cell 123 which will be decremented from 255 to 0. Then memory cell 122 can be incremented by 1 whereby again memory cells 121 and 123 remain unchanged. This process is repeated in the same manner, thus implementing a gray code type counter in which the content of only a single memory cell at a time is changed with any increment or decrement. The count sequence within a single memory cell 121, 122, or 123 is not critical and can be binary, decimal, gray code or any other suitable counting method.

After increment/decrement of the counter or in other words the change of the content of one of the memory cells 121, 122, or 123 a new checksum is calculated and stored in respective memory cells 131, 132, and 133. As can be easily seen from the respective formulas above, only two of the three memory cells 131, 132, 133 are affected by a single increment/decrement of the counter. In case of a value change in memory cell 123, memory cells 132 and 133 have to be updated. In case of a value change in memory cell 122, memory cell 131 and 132 have to be updated and in case of a value change in memory cell 121, memory cells 131 and 133 have to be updated.

The following procedure describes the evaluation of the content of the memory cells 120 which takes place every time before or after incrementing the counter. In a first step, the checksum of memory cells 131, 132, and 133 is evaluated to check whether any writing error occurred during update of these memory cells. Therefore, the content of all three memory cells 131, 132, and 133 are EXCLUSIVELY ORed; namely checksum=D⊕E⊕F. If all three memory cells contain the right content the result of this operation must be ‘0’. If not, a writing error to one of these cells occurred. In this case the content of all checksum memory cells has to be recalculated from the content of memory cells 121, 122, and 123 and rewritten to the respective memory cells 131, 132, and 133.

If the checksum is correct, namely equals ‘0’, then the content of memory cells 121, 122, and 123 is evaluated in a next step. To this end, it is checked whether the content of memory cells 121 and 122 EXCLUSIVELY ORed matches the content of memory cell 131 AND the content of memory cells 122 and 123 EXCLUSIVELY ORed matches the content of memory cell 132 AND the content of memory cells 121 and 123 EXCLUSIVELY ORed matches the content of memory cell 133. If this is true, the content of the counter is correct and the system can increment or decrement the counter value. This step can be speed up by only requiring two of the three tests to pass before proceeding.

In case the above operation fails, one of the counter memory cells got corrupted during the last write cycle. Thus, in a following step it is checked whether the content of memory cells 121 and 122 EXCLUSIVELY ORed matches the content of memory cell 131. If this is true, then memory cell 123 was corrupted and will be rewritten with the result of the EXCLUSIVELY ORed content of registers 122 and 132, namely C=E⊕B. Otherwise, it is checked whether the content of memory cells 122 and 123 EXCLUSIVELY ORed matches the content of memory cell 132. If this is true, then memory cell 121 was corrupted and will be rewritten with the result of the EXCLUSIVELY ORed content of registers 123 and 133, namely A=F⊕C. Otherwise, it is checked whether the content of memory cells 121 and 123 EXCLUSIVELY ORed matches the content of memory cell 133. If this is true, then memory cell 122 was corrupted and will be rewritten with the result of the EXCLUSIVELY ORed content of registers 121 and 131, namely B=D⊕A. The last comparison in this sequence can also be omitted as it is clear that at this point memory cells 121 and 123 contain the correct value and therefore memory cell 122 must have been corrupted. Furthermore, since these test are identical to the previous operation of checking, whether the counter value got corrupted, they can be combined for less complexity and faster results.

The process of writing to the memory cells according to the embodiment shown in FIG. 1 is done in a well known fashion via address, data and control lines. The exemplary embodiment of FIG. 2 works in a similar way. Memory cells 121, 122, and 123 are written the same way as explained above. The content of memory cells 131, 132, and 133 is calculated by elements 221, 222, and 223 and then written sequentially after update of one of the memory cells 121, 122, and 123. Depending on which counter cell has been updated, counter control unit 210 couples the output 241, 242, or 243 of counter control unit 210 or the outputs of memory cells 121, 122, 123 with the EXCLUSIVE OR gates 221, 222, 223, respectively. For example, counter control unit 210 can couple lines 241 directly with lines 231 and memory cell 121. In this case lines 232 and 233 are directly coupled with memory cells 122 and 123, respectively. The EXCLUSIVE OR gates 221, 222, and 223 calculate the new values of memory cells 131, 132, and 133 and counter control unit 210 initiates a write cycle sequentially for memory cell 121, 131, and 133.

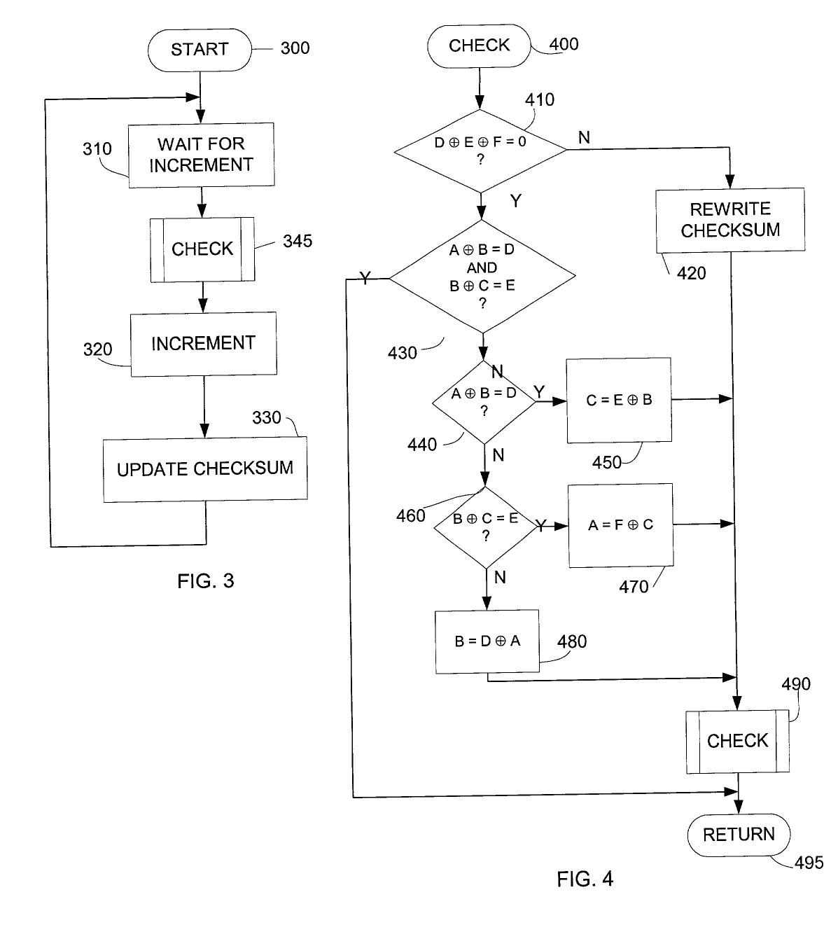

FIG. 3 depicts a flow chart showing the method of incrementing/decrementing of a counter according to one of the exemplary embodiments of the present application. The sequence starts with step 300. Then, in step 310 the system waits for an counter increment command. The next step 345 is a check-subroutine which will be explained later. In step 320 the counter value is incremented and one register is updated as described above. In the following step 330 the checksum is calculated and two checksum registers are updated sequentially. Then the program returns to step 310.

FIG. 4 depicts the check-subroutine in detail. The routine starts at step 400 followed by step 410 in which the checksum D⊕E⊕F=0 condition is tested. If the checksum is correct, step 430 follows, if not step 420 follows in which the checksum is recalculated and rewritten. After step 420 step 490 follows which calls again for the check-subroutine and then returns in step 495. Depending on the structure of the main routine, for example as shown in FIG. 3, step 490 can be skipped. In step 430 the counter value is checked. If correct the routine jumps to step 495 and returns. If incorrect, the routine goes to step 440 where the condition A⊕B=D is tested. If this condition is true, step 450 follows in which register C is set to E⊕B. After this step the routine jumps to step 490. If step 440 result is false, step 460 follows in which the condition B⊕C=E is tested. If true, the sequence follows up with step 470 in which register A is set to F⊕C followed by step 490. If step 460 result is false register B is set to D⊕A followed by step 490.

FIG. 5 depicts an exemplary embodiment of the counter proper including a code converter structure without showing the checksum registers. The code converter is capable of converting binary code into a base-2ⁿ-gray code according to the above mentioned exemplary embodiments. Same numerals depict same elements. The output of register 121 is coupled with the input of register 571. The least significant bit 501 of register 121 is connected with the control input of an inverter unit 523 and the first input of an EXCLUSIVE OR gate 521. The output of register 122 is coupled with the input of inverter unit 523 whose output is coupled with the input of register 572. The least significant bit 502 of register 122 is connected to a second input of EXCLUSIVE OR gate 521 whose output is coupled with the control input of an inverter unit 524. The input of inverter unit 524 is coupled with the output of register 123. The output of inverter unit 524 is coupled with the input of register 573. Registers 571, 572 and 573 are concatenated and form a single binary counter register which is coupled with incrementer/decrementer unit 550. As these registers are only used to increment/decrement in the binary domain they do not need to be non-volatile. The output of register 571 is coupled with associated lines of a bus 510. The output of register 572 is coupled with the input of another inverter unit 533 whose output is also coupled with associated lines of bus 510. The output of register 573 is coupled with the input of an inverter unit 532 whose output is coupled with respective lines of bus 510. The least significant bit 504 of register 571 controls inverter unit 533. The least significant bit 503 of register 572 is coupled with the control input of inverter unit 532. Control unit 500 comprises all circuitry necessary to control transfer from registers 121, 122, 123 to registers 571, 572, 573 and vice versa. Therefore, FIG. 5 shows a respective control bus 560 coupled with those registers. Of course, it is also possible to directly increment/decrement the base-2ⁿ-gray code without first converting it into a binary code.

This hardware solution provides the possibility of converting binary code into the base-2ⁿ-gray code suitable for the above described exemplary embodiments. The following Table 1 shows a partial sequence for a base-4-gray code using 2 bits per register and its binary and decimal equivalent.

TABLE 1

| binary | decimal | base-4-gray-code |
|---|---|---|
| 00 00 00 | 0 | 0 0 0 |
| 00 00 01 | 1 | 0 0 1 |
| 00 00 10 | 2 | 0 0 2 |
| 00 00 11 | 3 | 0 0 3 |
| 00 01 00 | 4 | 0 1 3 |
| 00 01 01 | 5 | 0 1 2 |
| 00 01 10 | 6 | 0 1 1 |
| 00 01 11 | 7 | 0 1 0 |
| 00 10 00 | 8 | 0 2 0 |
| 00 10 01 | 9 | 0 2 1 |
| 00 10 10 | 10 | 0 2 2 |
| 00 10 11 | 11 | 0 2 3 |
| 00 11 00 | 12 | 0 3 3 |
| 00 11 01 | 13 | 0 3 2 |
| 00 11 10 | 14 | 0 3 1 |
| 00 11 11 | 15 | 0 3 0 |
| 01 00 00 | 16 | 1 3 0 |
| 01 00 01 | 17 | 1 3 1 |
| 01 00 10 | 18 | 1 3 2 |
| 01 00 11 | 19 | 1 3 3 |
| 01 01 00 | 20 | 1 2 3 |
| 01 01 01 | 21 | 1 2 2 |
| . . . | . . . | . . . |

As can be seen in Table 1, the gray code sequence has changes in only one digit and therefore in only one of the three registers whereas the binary code has often more than one register changed. For example, if registers 121, 122, 123 are 2 bit registers and contain the base-4-gray code at decimal position 17, register 121 contains 01, register 122 contains 11 and register 123 contains 01. To convert this code into a binary code control unit 500 activates transfer to binary registers 571, 572, and 573. Thus, register 571 becomes 01. The least significant bit of register 121 controls inverter unit 523. As the least significant bit 501 is set to 1, inverter unit 523 is activated and transfers the inverted content of register 122 into register 572. Thus, register 572 now contains 00. EXCLUSIVE OR gate 521 receives significant bit 501 and significant bit 502 each being set to 1. The output of EXCLUSIVE OR gate 521 is thus 0. Therefore, inverter unit 524 is not activated and transfers the content of register 123 unchanged into register 573, namely 01. The resulting content of concatenated registers 571, 572, and 573 is thus 01 00 01 which is the associated binary code according to Table 1. A binary increment or decrement can now be performed by the arithmetic unit 550.

Conversion from a binary code to a base-4-gray code will be explained as follows. Assuming registers 571, 572, and 573 contain the binary code for the decimal position 21. Registers 571, 572, and 573 then all contain 01. If control unit 500 initiates a transfer to register 121, 122, and 123 via bus 510, the content of register 571 is directly transferred into register 121 resulting in code 01. As the least significant bit 504 of register 571 is set to 1, inverter unit 533 is activated and the content of register 572 is inverted and then transferred to register 122, resulting in code 10. Also, as the least significant bit 503 of register 572 is set to 1, inverter unit 532 is activated and inverts the content of register 573, thus resulting in a code 10 being transferred into register 123. The resulting concatenated code in registers 121, 122, and 123 is then 01 10 10=122, which represents the base-4-gray code for decimal position 21 as shown in Table 1.

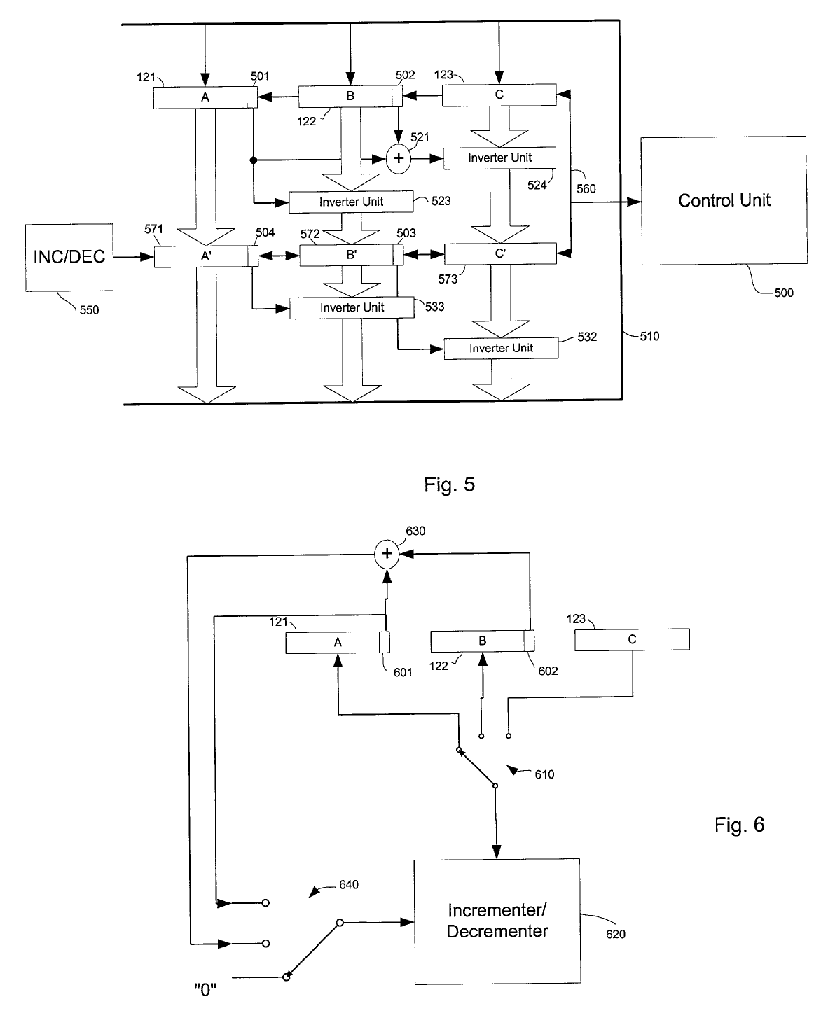

FIG. 6 shows another exemplary embodiment in which the increment/decrement procedure takes place in the base-2ⁿ-gray code domain. Again registers 121, 122, and 123 are concatenated to represent the counter value. An EXCLUSIVE OR gate 630 receives two input signals from the least significant bit 601 of register 121 and from the least significant bit 602 from register 122. The output of EXCLUSIVE OR gate 630 is coupled with a first select input of a switch 640. The least significant bit of register 121 is furthermore connected with a second select input of switch 640 whose third select input is coupled with a logical 0. The select terminal of switch 640 is connected with the control input of an incrementer/decrementer unit 620. A logical 0 selects an increment function and a logical 1 selects a decrement function of incrementer/decrementer unit 620. A select switch 610 couples the input/output of incrementer unit 620 with inputs/outputs of registers 121, 122, and 123. Both switches 610 and 640 are coupled in their select function as shown in FIG. 6.

This embodiment is in particular suitable for applications in which the base-2ⁿ-gray code does not have to be converted into binary code. A control unit (not shown) controls switches 610 and 640 in accordance to which register has to be changed. This can be realized easily by a state machine as the sequence is constant. See also Table 1. If register 121 is selected, then incrementer/decrementer unit 620 is always in increment mode. If register 122 is selected to be updated, then the least significant bit 601 of register 121 controls the function of incrementer/decrementer unit 620. Finally, if register 123 has been selected, then the output of EXCLUSIVE OR gate controls the function of incrementer/decrementer unit 620. Thus, the sequence according to Table 1 will be generated. If a descending sequence is needed, the embodiment according to FIG. 6 can be easily adapted by inserting an inverter before the control input of incrementer/decrementer unit 620.

A software solution for providing the above explained conversion function will be explained below. Table 2 shows a software code sequence suitable for a PIC®-microcontroller from Microchip Technology Inc. to convert base-2ⁿ-gray code into binary code.

TABLE 2

| | |
|---|---|
| btfsc | A, 0 |
| comf | B, f |
| btfsc | B, 0 |
| comf | C, f |

In this sequence the first instruction (btfsc=bit test file, skip if clear) tests the least significant bit of A. In case this bit is ‘0’ the sequence skips the next instruction (comf=complement file). In case this bit is set, the next instruction (comf) inverts the content of register B and writes the result back into this register. The following instruction (btfsc) tests the least significant bit of register B and skips the next instruction if it is ‘0’. Otherwise, the final instruction (comf) inverts the content of register C and writes back the result into this register.

As can be readily seen, this instruction sequence performs the same function as the hardware solution described in accordance with FIG. 5. An EXCLUSIVE OR function is not needed here because the third function is performed on an eventually altered register B. Alteration of register B in combination with the bit test function results therefore in an EXCLUSIVE OR function.

Table 3 shows a similar code sequence for converting a binary code back into a base-2ⁿ-gray code. Again the code is written in assembler language suitable for a PIC®-microcontroller from Microchip Technology Inc.

TABLE 3

| | |
|---|---|
| btfsc | B, 0 |
| comf | C, f |
| btfsc | A, 0 |
| comf | B, f |

In this sequence the first instruction (btfsc) tests the least significant bit of B. In case this bit is ‘0’ the sequence skips the next instruction (comf). In case this bit is set, the next instruction (comf) inverts the content of register C and writes the result back into this register. The following instruction (btfsc) tests the least significant bit of register A and skips the next instruction if it is ‘0’. Otherwise, the final instruction (comf) inverts the content of register B and writes back the result into this register.

Again, this instruction sequence performs a similar function as described in accordance with FIG. 5 and the binary to base-2ⁿ-gray code conversion. Both sequences can be easily implemented in a microcontroller or microprocessor 100 as shown in FIG. 1.

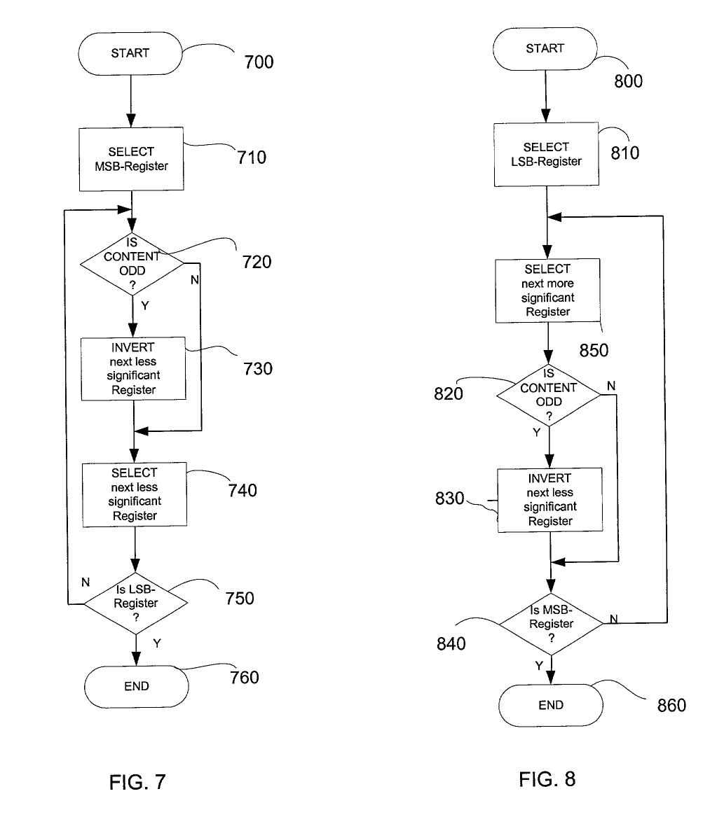

FIG. 7 shows a respective flow chart for the conversion of base-2ⁿ-gray code to binary code. The instruction sequence starts with step 700. In step 710 the most significant register (register A according to FIG. 5) is selected. If the content is odd the sequence branches to step 740. If the content is even the register following next in direction to the least significant register (Register B according to FIG. 5) is inverted. In step 740 the register following next in direction to the least significant register (Register B according to FIG. 5) is selected and the sequence jumps back to step 720 if in step 750 it is decided that this is not the least significant register. Otherwise, the sequence ends in step 760.

FIG. 8 shows a respective flow chart for the conversion of binary code back into base-2ⁿ-gray code. The instruction sequence starts with step 800. In step 810 the least significant register is selected. In the following step 850 the register preceding the current selected register in direction to the most significant register (register B′ according to FIG. 5) is selected. In step 820 it is checked whether the content is odd. If not, the sequence branches to step 840. If the content is even the register following next in direction to the least significant register (Register C′ according to FIG. 5) is inverted. In step 840 it is checked whether the current selected register is the most significant register. If yes, the sequence ends in step 860. Otherwise, the sequence loops back to step 850.

The exemplary embodiments show solutions for recoverable counter whereby the counter value is stored in three separate registers or memory cells. This concept can be easily adapted to more or even less registers as can be readily seen from the present specification. For an embodiment with four counter registers, at least four checksum registers are necessary. For example, counter registers are X1, X2, X3, X4 and checksum registers could be Y1, Y2, Y3, Y4, whereby Y1=X1⊕X2; Y2=X2⊕X3; Y3=X3⊕X4; and Y4=X1⊕X4. A plurality of other combinations for the checksum registers is possible for such an embodiment. However, at least four checksum registers are necessary to perform this checksum and recovery function.

An embodiment with two counter registers is also possible, however, the three checksum registers would then contain the contents A, B, A⊕B. Furthermore an embodiment with only one counter register is also possible. However, as explained before, three registers must still change per each counter operation resulting in two checksum registers, both containing a copy of A. An improvement on this would be to invert one copy of A and have the checksum test function return −1 if the checksum is OK. In these special cases there is one more checksum register than counter registers.

The invention, therefore, is well adapted to carry out the objects and attain the ends and advantages mentioned, as well as others inherent therein. While the invention has been depicted, described, and is defined by reference to exemplary embodiments of the invention, such references do not imply a limitation on the invention, and no such limitation is to be inferred. The invention is capable of considerable modification, alternation, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects.

What is claimed is:

1. Counter arrangement comprising a plurality of counter registers and at least the same number of checksum registers being controlled by control means, whereby the counter control means change the content of only one of the counter registers for each change in the counting sequence and comprise means to update the checksum registers, whereby the content of each checksum registers is defined by an associated function which allows recovery of the content of each counter register and a function performed on the content of all checksum registers results in a constant value.

2. Counter arrangement according to claim 1, wherein respective sets of two counter registers from the plurality of counter registers are coupled with an associated checksum register through a functional unit.

3. Counter arrangement according to claim 2, wherein the functional unit performs a logical function.

4. Counter arrangement according to claim 2, wherein the functional unit performs an arithmetic function.

5. Counter arrangement according to claim 2, wherein the functional unit is an EXCLUSIVE OR gate.

6. Counter arrangement according to claim 1, wherein the control unit comprises an incrementer/decrementer unit selectively coupled with one of the counter registers.

7. Counter arrangement comprising:
a control unit;
first, second, and third registers coupled with said control unit;
fourth, fifth, and sixth registers coupled with said control unit;
first, second, and third functional units each having two inputs and an output;
wherein
the inputs of the first functional unit being coupled with the first and second register, respectively and the output with the fourth register;
the inputs of the second functional unit being coupled with the second and third register, respectively and the output with the fifth register;
the inputs of the third functional unit being coupled with the first and third register, respectively and the output with the sixth register; and wherein
the control unit performs a counter function on the first, second, and third registers such that the content of only one of the counter registers changes for each change in a counting sequence.

8. Counter arrangement according to claim 1, wherein the functional units perform a logical function.

9. Counter arrangement according to claim 1, wherein the functional units perform an arithmetic function.

10. Counter arrangement according to claim 7, wherein the functional units are EXCLUSIVE OR gates.

11. Counter arrangement according to claim 7, further comprising:
an incrementer/decrementer unit having a control input for selecting an increment or a decrement function;
a first select switch for coupling the incrementer/decrementer unit with one of the first, second, or third registers;
an EXCLUSIVE OR gate having two inputs and an output, whereby the first input is coupled with the least significant bit of the first register and the second input is coupled with the least significant bit of the second register;
a second select switch functionally coupled with the first select switch for coupling the output of the EXCLUSIVE OR gate, the least significant bit of the first register or a logical 0 with the control input of the incrementer/decrementer unit.

12. Counter arrangement according to claim 7, further comprising:
a seventh, eighth, and ninth register;
a first and second controllable inverter unit for either inverting or non-inverting a signal; and
an EXCLUSIVE OR gate having two inputs and an output; whereby
the first register is coupled with the seventh register;
the second register is coupled through the first inverter unit with the eighth register;
the third register is coupled through the second inverter unit with the ninth register; and whereby
the least significant bit of the first register is coupled with the first input of the EXCLUSIVE OR gate and with the control input of the first inverter unit; and
the least significant bit of the second register is coupled with the second input of the EXCLUSIVE OR gate whose output is coupled with the control input of the second inverter unit.

13. Counter arrangement according to claim 12, further comprising:
a third and fourth controllable inverter unit; wherein
the seventh register is coupled with the first register;
the eighth register is coupled through the third inverter unit with the second register;
the ninth register is coupled through the fourth inverter unit with the third register; and whereby
the least significant bit of the seventh register is coupled with the control input of the third inverter unit; and
the least significant bit of the eighth register is coupled with the control input of the fourth inverter unit.

14. Counter arrangement according to claim 13, wherein the seventh, eighth and ninth registers are concatenated and further comprising an incrementer/decrementer unit coupled with the concatenated registers.

15. Method for operating a counter comprising a plurality of counter registers and at least the same number of checksum registers, comprising the steps of:
changing the value of only one of the counter registers with every change in a counting sequence;
calculating the value of the associated checksum registers as a function of the content of at least two counter registers such that a checksum calculated from all checksum registers results in a constant value.

16. Method according to claim 15, wherein a logical function is used.

17. Method according to claim 15, wherein an arithmetic function is used.

18. Method according to claim 16, wherein an EXCLUSIVE OR function is used.

19. Method according to claim 15, wherein the step of changing the value further comprises the steps of:
converting the content of all counter registers into binary code;
incrementing or decrementing said binary code;
converting said changed binary code back.

20. Method according to claim 19, wherein the step of converting the content into binary code comprises the steps of:
(a) selecting a most significant register;
(b) testing whether the content of the selected register is odd and if yes, inverting the content of the following register;
(c) ending the conversion if the following register is the least significant register;
(d) otherwise selecting the following register and repeating steps (b) through (d).

21. Method according to claim 19, wherein the step of converting the content from binary code comprises the steps of:
(a) selecting the register preceding the least significant register;
(b) testing whether the content of the selected register is odd and if yes, inverting the content of the following register;
(c) selecting the preceding register and repeating steps (b) through (c).

22. Method according to claim 15, wherein changing the value of one counter registers comprises the step of incrementing the value of the register by “1”.

23. Method according to claim 15, wherein changing the value of one counter registers comprises the step of decrementing the value of the register by “1”.

24. Method according to claim 15, wherein changing the value of one counter registers comprises the step of using a gray code for increments or decrements.

25. Method according to claim 15, wherein changing the value of the counter registers comprises the step of:
(a) incrementing a first register to its maximum value for each value change;
(b) incrementing a second register for the next value change;
(c) decrementing the first register to its minimum value for each following value change;
(d) incrementing the second register for the next value change;
(e) repeating steps (a) through (d).

26. Method according to claim 15, wherein changing the value of the counter registers comprises the step of:
(a) decrementing a first register to its maximum value for each value change;
(b) decrementing a second register for the next value change;
(c) incrementing the first register to its minimum value for each following value change;
(d) decrementing the second register for the next value change;
(e) repeating steps (a) through (d).
